(19) United States
(12) Patent Application Publication
(10) Pub. No.: US 2007/0155036 A1
(43) Pub. Date: Jul. 5, 2007

(54) Method for Manufacturing CMOS Image Sensor

(76) Inventor: Hee Sung Shim, Gangneung-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/612,577

(22) Filed: Dec. 19, 2006

(30) Foreign Application Priority Data
Dec. 29, 2005 (KR) 10-2005-0134176

(51) Int. Cl. H01L 21/00

(52) U.S. Cl. 438/48

(57) ABSTRACT

A method for manufacturing a CMOS image sensor capable of improving a low illumination characteristic is provided. The method includes: forming a photodiode and a gate poly of a transfer transistor on a semiconductor substrate; depositing a spacer material on the semiconductor substrate including the photodiode and the gate poly of the transfer transistor; and implanting p-type impurity ions in an upper portion of the photodiode through the spacer material deposited on the photodiode. Embodiments of the subject method can prevent ion damage of a surface of the photodiode caused by a dry etching process for forming spacers at sidewalls of the gate poly of a transfer transistor from occurring, which may improve a low illumination characteristic of the image sensor.

### RELATED APPLICATION(S)

This application claims the benefit under 35 U.S.C. §119(e) of Korean Patent Application No. 10-2005-0134176 filed Dec. 29, 2005, which is incorporated herein by reference in its entirety.

### FIELD OF THE INVENTION

The present invention relates to a complementary metal oxide silicon (CMOS) image sensor, and more particularly, to a method for manufacturing a CMOS image sensor capable of improving a low illumination characteristic caused by crystal defects at an upper portion of a photodiode.

### BACKGROUND OF THE INVENTION

In general, an image sensor is a semiconductor device that transforms an optical image to electrical signals. The image sensor is generally classified as a charge coupled device (CCD) or a CMOS image sensor. A CCD type image sensor includes several MOS (metal oxide semiconductor) capacitors, closely positioned to one another, in which electric charge carriers are transferred to or saved in the MOS capacitors.

On the other hand, a CMOS image sensor has incorporated a switching mode by forming MOS transistors for each unit pixel with CMOS technology, and using control circuits and signal-processing circuits in conjunction with the MOS transistors to sequentially detect outputs of the photodiodes.

The CCD has various disadvantages, such as a complicated driving mode, high power consumption, inability to incorporate a signal processing circuit on-chip for the CCD due to the many mask processes, and so on. Currently, in order to overcome these disadvantages, the CMOS image sensor is being developed using sub-micron CMOS manufacturing technology.

The CMOS image sensor obtains an image from the formation of a photodiode and a MOS transistor within a unit pixel to detect signals using a switching mode. As mentioned above, because the CMOS image sensor makes use of CMOS manufacturing technology, the CMOS image sensor has low power consumption, as well as a single manufacturing process requiring about 20 masks compared with the CCD manufacturing process requiring 30 to 40 masks. As a result, the CMOS image sensor can integrate a signal processing circuit into a single chip. Accordingly, the CMOS image sensor is currently used in various applications, such as digital still cameras (DSC), PC cameras, mobile cameras, and so forth.

The CMOS image sensor is classified as a 3T type, a 4T type or a 5T type according to the number of transistors formed in a unit pixel. The 3T type CMOS image sensor includes a single photodiode and three transistors, and the 4T type CMOS image sensor includes a single photodiode and four transistors.

Hereinafter, a method for manufacturing a CMOS image sensor according to the related art will be explained with reference to the accompanying drawings.

FIG. 1 is an equivalent circuit diagram of a 4T type CMOS image sensor according to the related art.

As shown in FIG. 1, the unit pixel of the CMOS image sensor includes a photodiode (PD) 10 as a photoelectric transducer and four transistors.

Here, the four transistors include a transfer transistor Tx, a reset transistor Rx, a drive transistor Dx, and a select transistor Sx. A load transistor (also shown) is electrically connected to the drain of the select transistor Sx, which is an output terminal of the unit pixel.

FIGS. 2 through 4 are cross-sectional views of a CMOS image sensor for describing a method of manufacturing a CMOS image sensor according to the related art.

As shown in FIG. 2, in the a method of manufacturing a CMOS image sensor according to the related art, a device isolation region 11 and an active region are formed on a semiconductor substrate 10. Here, the active region may generally be referred to as the remaining region of the substrate not having the device isolation region 11 formed therein.

Next, a gate poly 20 for a transistor is formed at a predetermined part of the active region in the semiconductor substrate 10. In the cross-section shown in FIG. 2, the gate poly 20 corresponds to the transfer transistor Tx shown in FIG. 1.

Referring to FIG. 2, an entire surface of the resulting structure is coated with a photoresist layer, and exposure and developing processes are performed to form a photoresist pattern 30 exposing one side of the gate poly 20 and a photodiode region.

Then, an n-type impurity ion is implanted in the semiconductor substrate 10 using the photoresist pattern 30 as a mask to form a photodiode 40 having a predetermined depth.

Referring to FIG. 4, the photoresist pattern 30 is removed, and a nitride layer or an oxide layer is deposited on an entire surface of the semiconductor substrate 10 including the gate poly 20.

Then, spacers 35 are formed at both sides of the gate poly 20 by a dry etching process.

Thereafter, an entire surface of a resulting object is coated with a photoresist layer, and exposure and developing processes are carried out to form a second photoresist pattern 33 for exposing the photodiode region 40.

Then, a p-type impurity ion is implanted using the second photoresist pattern 33 as a mask to form a p-type impurity region 50 at a surface of the photodiode region 40.

However, the CMOS image sensor according to the related art has following problems.

When spacer material layers formed at an upper surface of the photodiode are dry-etched, crystal defects in the upper surface of the photodiode increase due to the ion damage and may cause dark current of the CMOS image sensor to increase.

In addition, in the CMOS image sensor according to the related art, during a manufacturing process thereof a p-type doping is performed in an upper portion of the photodiode. This p-type region is formed to isolate an n-type photodiode from crystal defect layers such as dangling bonds present at the surface of the photodiode.

However, crystal defects due to the ion implantation itself may occur during the p-type ion implantation procedure.

### BRIEF SUMMARY

Accordingly, embodiments of the present invention are directed to a method for manufacturing a CMOS image sensor that substantially obviates one or more problems due to limitations and disadvantages of the related art.

An object of embodiments of the present invention is to provide a method for manufacturing a CMOS image sensor capable of improving a low illumination characteristic of the CMOS image sensor. Another object is to minimize a formation of an electron-hole pair in the CMOS image sensor caused by crystal defects present at an upper portion of an n-type photodiode.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for manufacturing a CMOS (complementary metal oxide silicon) image sensor comprising: forming a photodiode and a gate poly of a transfer transistor on a semiconductor substrate; depositing a spacer material on the semiconductor substrate including the photodiode and the gate poly of the transfer transistor; and implanting a p-type impurity ion in an upper portion of the photodiode through the spacer material deposited on the photodiode.

In one embodiment of the present invention, the spacer material can be a nitride layer or an oxide layer.

In one embodiment of the present invention, the step of implanting the p-type impurity ion in an upper portion of the photodiode can be performed using a mask shielding a remaining region except for the photodiode.

In another embodiment of the present invention, there is provided a method for manufacturing a CMOS (complementary metal oxide silicon) image sensor comprising: preparing a semiconductor substrate in which a device isolation region and an active region are defined; forming a gate poly at a predetermined part of the active region; implanting an n-type impurity ion in the active region located at a side of the gate poly to form a photodiode region having a predetermined depth; depositing a spacer material on the semiconductor substrate including the photodiode and the gate poly; and implanting a p-type impurity in a upper surface of the photodiode through the spacer material deposited on the photodiode.

In a preferred embodiment of the present invention, the active region is made of a p-type semiconductor.

In an embodiment of the present invention, the spacer material can be a nitride layer or an oxide layer.

In an embodiment of the present invention, the gate poly is a gate poly of a transfer transistor for a CMOS image sensor.

In another embodiment of the present invention, the step of implanting the p-type impurity ion in a surface of the upper portion of the photodiode can be performed using a mask shielding a remaining region except for the photodiode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is an equivalent circuit diagram of a 4T CMOS image sensor according to the related art;

FIGS. 2 through 4 are cross-sectional views of a CMOS image sensor for describing a method of manufacturing a CMOS image sensor according to the related art; and

FIGS. 5A through 5D are cross-sectional views of a CMOS image sensor for describing a method of manufacturing a CMOS image sensor according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a method for manufacturing a CMOS image sensor according to an embodiment of the present invention will be described with reference to the accompanying drawings.

Embodiments of the present invention can provide a method for manufacturing a CMOS image sensor capable of improving a low illumination characteristic by minimizing a formation of an electron-hole pair in the CMOS image sensor due to crystal defects present at an upper portion of an n-type photodiode, while not minimizing the electron-hole pair (EHP) generated by light.

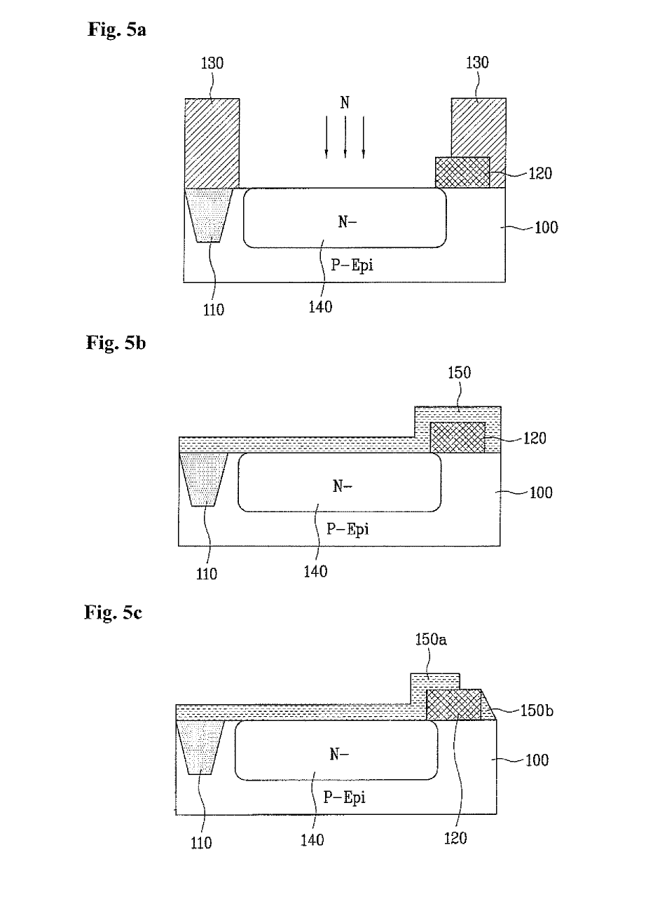

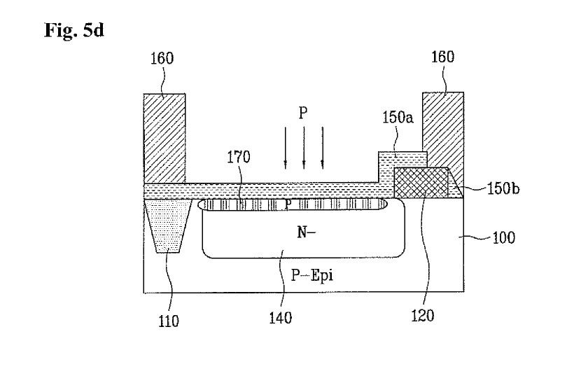

FIGS. 5A through 5D are cross-sectional views of a CMOS image sensor for describing a method of manufacturing a CMOS image sensor according to an embodiment of the present invention. More particularly, FIGS. 5A through 5D show cross-sectional views of a photodiode region and a poly gate region of a transfer transistor for a CMOS image sensor.

Referring to FIG. 5A, a semiconductor substrate 100 can be prepared in which a device isolation region 110 and an active region are defined. Regions where the device isolation layer 110 is not formed can be defined as an active region.

Next, a gate poly 120 for a transfer transistor can be formed on a predetermined part of the active region of the semiconductor substrate 100. Although not shown, gate polys of remaining transistors for a CMOS image sensor can also be formed during the formation of the gate poly 120.

Next, a first photoresist pattern 130 can be formed to expose a portion of the substrate at a side of the gate poly 120. An n-type impurity ion can be implanted in the semiconductor substrate 100 using the first photoresist pattern 130 as a mask to form a photodiode region 140 having a predetermined depth.

Referring to FIG. 5B, a nitride layer or an oxide layer 150 can then be deposited on an entire surface of the semiconductor substrate 100 including the gate poly 120.

Thereafter, as shown in FIG. 5C, a portion of the nitride or oxide layer 150 at one side of the gate poly 120 can be dry-etched to form a spacer 150b. At this time, the nitride layer or the oxide layer 150 deposited at an entire surface of the upper portion of the photodiode is not dry-etched. Namely, the spacer material layer 150a deposited on the photodiode 140 is not dry-etched.

Because the upper surface of the photodiode is not dry-etched during spacer formation, a lower illumination characteristic degradation of an image sensor due to the ion damage can be better prevented in comparison with the related art.

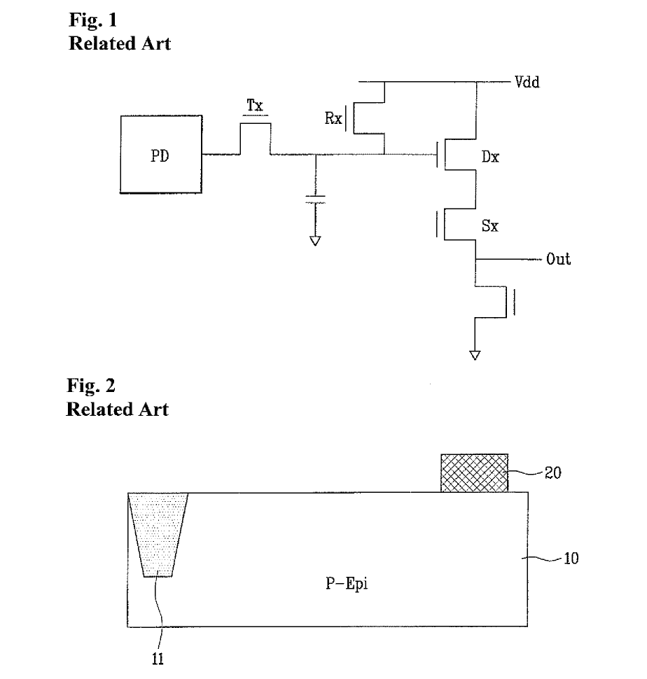

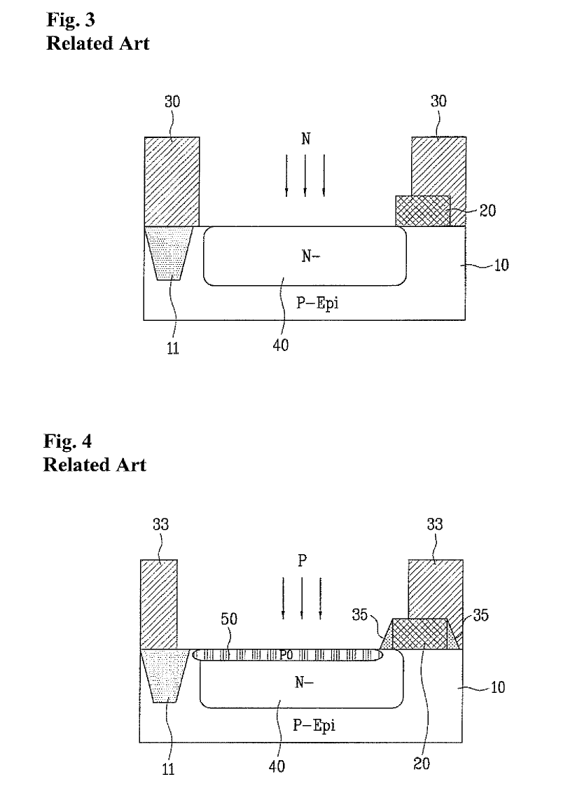

Referring to FIG. 1D, a p-type impurity can be implanted into a top surface of the photodiode 140. The p-type impurity can be implanted in the surface of the photodiode region 140 using a third photoresist pattern 160 that exposes the photodiode region as a mask while the spacer material layer 150a remains on the upper portion of the photodiode 140. That is, p-type impurity can be implanted into the photodiode region through the spacer material layer.

In a specific embodiment, as shown in FIG. 5D, the spacer material layer 150a made of the nitride layer or the oxide layer can be present on the photodiode region. A third photoresist pattern 160 can be formed on the substrate to expose the spacer material 150a on the photodiode region 140.

Next, a p-type impurity can be implanted at an upper surface of the photodiode region by an ion implantation process to form a pinned photodiode structure.

In the present invention described above, it may be understood that an entire surface of an upper portion of the photodiode region 140 can be present in a state from which the spacer material layer 150a is removed.

Accordingly, the present invention has an advantage in that it can prevent the occurrence of an ion damage in a surface of an upper portion of the photodiode caused by removing the spacer material layer 150a by a dry etching process.

Further, in the present invention, because the p-type impurity is implanted in the upper surface of the photodiode region in a state having the spacer material layer 150a thereupon, it may minimize the implant damage, which can be generated in a silicon substrate Si.

In the embodiment described above, the p-type impurity ion is implanted in the upper surface of the photodiode in a step as shown in FIG. 5D. In another embodiment of the subject method, the p-type impurity ions can be implanted in the upper surface of the photodiode in a step prior to etching the spacer material 150, for example before the step illustrated in FIG. 5C.

That is, as shown in FIG. 5B, after the nitride layer or the oxide layer 150 has been formed on the substrate, the p-type impurity can be implanted in the upper portion of the photodiode.

In a further embodiment, after a dry etching process has been performed to form the spacers 150b as shown in FIG. 5C, the p-type impurity may be implanted in the upper portion of the photodiode region using the spacer material layer 150a deposited at the upper portion of the photodiode region as a buffer layer.

For the embodiments when the impurity ions are implanted between the steps illustrated in FIGS. 5B and 5C, the p-type impurity ion can be preferably implanted in a surface of the photodiode region using a mask shielding the remaining regions except for the photodiode region.

It will be apparent to those skilled in the art that various modifications and variations can be made in the present invention. Thus, it is intended that the present invention covers the modifications and variations of this invention provided they come within the scope of the appended claims and their equivalents.

As is clear from the forgoing description, embodiments of the method for manufacturing the CMOS image sensor according to the present invention can have the following effects.

First, ion damage of a surface of a photodiode caused by a dry etching process for forming spacers at sidewalls of a gate poly for a transistor can be prevented, which may improve a low illumination characteristic of the image sensor.

Second, by using a spacer material layer as a buffer layer, embodiments of the present invention can minimize the damage due to an ion implantation during the p-type impurity implantation in the upper surface of a photodiode.

I claim:

1. A method for manufacturing a CMOS (complementary metal oxide silicon) image sensor comprising:
forming a photodiode and a gate poly of a transfer transistor on a semiconductor substrate;
depositing spacer material on the semiconductor substrate including the photodiode and the gate poly of the transfer transistor; and
implanting p-type impurity ions in an upper surface portion of the photodiode through the spacer material deposited on the photodiode.

2. The method according to claim 1, wherein the spacer material is a nitride layer or an oxide layer.

3. The method according to claim 1, wherein implanting the p-type impurity ions in an upper surface portion of the photodiode, comprises:
forming a mask pattern on the semiconductor substrate exposing the spacer material on the photodiode; and
implanting p-type impurity ions through the spacer material into the upper surface portion of the photodiode using the mask pattern as a mask.

4. A method for manufacturing a CMOS (complementary metal oxide silicon) image sensor comprising:
preparing a semiconductor substrate in which a device isolation region and an active region are defined;
forming a gate poly at a predetermined part of the active region;
implanting an n-type impurity ion in the active region at one side of the gate poly to form a photodiode having a predetermined depth;
depositing spacer material on the semiconductor substrate including the photodiode and the gate poly; and
implanting a p-type impurity ions in an upper surface of the photodiode through the spacer material deposited on the photodiode.

5. The method according to claim 4, wherein the active region is made of a p-type semiconductor.

6. The method according to claim 4, wherein the spacer material is a nitride layer or an oxide layer.

7. The method according to claim 4, wherein the gate poly is a gate poly of a transfer transistor for a CMOS image sensor.

8. The method according to claim 4, wherein implanting the p-type impurity ions in an upper surface of the photodiode comprises:
forming a mask pattern on the semiconductor substrate exposing the spacer material on the photodiode; and
implanting p-type impurity ions through the spacer material into the upper surface of the photodiode using the mask pattern as a mask.
